(19) United States
(12) Patent Application Publication
(10) Pub. No.: US 2013/0171442 A1
(43) Pub. Date: Jul. 4, 2013

(54) METHOD FOR MODIFYING POROUS SUBSTRATE AND MODIFIED POROUS SUBSTRATE

(71) Applicants: Meng-Chang LIN, (US); Yu-Li Lin, (US); Yen-Hsun Chi, (US); Jun-Yen Uan, (US)

(72) Inventors: Meng-Chang LIN, (US); Yu-Li Lin, (US); Yen-Hsun Chi, (US); Jun-Yen Uan, (US)

(21) Appl. No.: 13/557,763

(22) Filed: Jul. 25, 2012

(30) Foreign Application Priority Data
Dec. 30, 2011 (TW) 100149772

(51) Int. Cl. B32B 3/26; C25D 11/24; C23C 16/06; B05D 3/02; C23C 16/00

(52) U.S. Cl. 428/315.5; 427/372.2; 427/255.33; 427/255.34; 427/255.31; 205/229; 428/319.1

(57) ABSTRACT

A method for modifying a porous substrate, including: coating a metal hydroxide layer on a porous substrate; and calcining the porous substrate with the metal hydroxide layer coated thereon to transform the metal hydroxide layer into a continuous metal oxide layer, forming a modified porous substrate. The disclosure also provides a modified porous substrate.

### CROSS REFERENCE TO RELATED APPLICATIONS

This application claims priority of Taiwan Patent Application No. 100149772, filed on Dec. 30, 2011, the entirety of which is incorporated by reference herein.

### BACKGROUND

1. Technical Field

The present disclosure relates to a method for modifying a porous substrate and a modified porous substrate, and in particular relates to a method for modifying a porous substrate and a modified porous substrate used for separating gas mixtures.

2. Description of the Related Art

Hydrogen energy is less harmful to the environment and can be continuously recycled and reused, and it is a new energy source with bright prospects. Steam reforming is the major process for generating hydrogen. However, since steam reforming is highly endothermic, an extremely high temperature is required to obtain sufficient conversion rates for thermodynics reasons. When the reaction pressure is 1000 kPa and the ratio of water to methane is 3, a reaction temperature of 850° C. is required for a methane conversion rate of 90%. For steam reforming, if 90% of the hydrogen gas can be removed in time, then the reaction temperature required may only be 500° C. A film of palladium or its alloy may be used to separate and purify hydrogen gas. By incorporating a film of palladium or its alloy in the steam reforming reactor, the selective hydrogen permeation mechanism of palladium or its alloy with its selective hydrogen permeation characteristics may shift thermodynamic equilibrium by selectively separating hydrogen from syngas in the steam reforming reactor, thus enhancing the hydrogen conversion rate. The mechanism of hydrogen permeation of palladium involves the adsorption of hydrogen gas onto the surface of palladium with a higher hydrogen gas concentration (reaction side), the dissociation of adsorbed hydrogen gas into hydrogen atoms, and subsequent dissolution of the hydrogen atoms into the interior of the palladium and then diffusion to another end where the hydrogen gas concentration is lower (permeation side). The hydrogen atoms diffused to the surface at the end with a lower hydrogen gas concentration are then re-bonded to become hydrogen molecules, which are desorbed from the surface. The flux of hydrogen gas may be described with the formula:

$$J = \frac{{Q}_{0}}{L} exp ( - \frac{E}{RT} ) ( {P}_{{H}_{2} , h}^{n} - {P}_{{H}_{2} , 1}^{n} ) ,$$

wherein Q₀ is the permeability constant, L is the thickness of the Pd film, and E is the activation energy for permeation. Other than being influenced by temperature and pressure, the flux of hydrogen gas is even more influenced by the Pd film, the thickness of which is inversely proportional to the flux of hydrogen gas. The thinner the Pd film, the higher the hydrogen gas flux and the lower the costs. However, if the Pd film is too thin, it cannot withstand the reaction environment with high temperature and the high pressure, so Pd composite films have been developed for this reason, the strength of the film and the hydrogen gas flux may be increased by plating palladium metal on a porous substrate. In recent years, Pd composite films have been widely studied, and common materials for porous substrates comprise porous stainless steel, porous ceramics and so on. The porous ceramics are inexpensive and have small and uniform pores as well as low surface roughness, making porous ceramics a promising material for forming a compact layer. However, the difference in coefficients of thermal expansion (CTE) between ceramic materials and Pd metal is large, and separation of Pd metal from the ceramic material may easily occur under high temperatures. Furthermore, since ceramic materials are brittle, it is difficult to assemble ceramic materials with a reactor. In comparison, porous stainless steel substrates with thermal expansion coefficients close to that of Pd metal may be easily assembled with Pd metal and have great mechanical strength and malleability. Thus, porous stainless steel substrates are more commonly used substrates for the Pd composite films in reactors. However, the downside of using porous stainless steel substrates is that the surface pores are not only too large but also non-uniformly distributed. Mardilovich et al. found that when a Pd film is plated on a porous stainless steel substrate by using electro-less plating, the film thickness required for forming a compact Pd film is about three times the largest pore size of the substrate. Therefore, when the pores of the substrate have a larger size, since the hydrogen gas flux and the Pd film thickness are inversely proportional, a high hydrogen gas flux may not be obtained. Thus, it is necessary to form a modifying layer of porous stainless steel substrates. A common modifying method for pores of a substrate is to cover the substrate surface with a layer of oxide (silicon oxides, aluminum oxides, zirconium oxide and so on), which is used to decrease the pore size of the substrate and to impede diffusion. Aluminum oxide particles have been proposed to be filled into the pores of a metal porous substrate to obtain a uniform surface, and this can lower the film thickness required for forming a compact Pd film. However, there are drawbacks such as decreased lifetime and ineffective hydrogen purification. Therefore, it is necessary to develop a method for fabricating a suitable modifying layer on a porous substrate.

### SUMMARY

The present disclosure relates to a method for modifying a porous substrate, comprising: coating a metal hydroxide layer on a porous substrate; and calcining the porous substrate having the metal hydroxide layer to transform the metal hydroxide layer into a continuous metal oxide layer, forming a modified porous substrate.

The present disclosure also relates to a modified porous substrate, comprising: a porous substrate; and a continuous metal oxide layer, coated on the porous substrate, wherein the continuous metal oxide layer comprises a second metal that is different from a first metal corresponding to a metal of the metal oxide layer.

A detailed description is given in the following embodiments with reference to the accompanying drawings.

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims. When one layer is described to be on or above another layer (or substrate), the layer may be in direct contact with the another layer (substrate), or there may be an intervening layer between the two layers.

The disclosure is related to a method for modifying porous substrate and a modified porous substrate, wherein a metal hydroxide layer is first formed on the porous substrate, and the metal hydroxide layer is then calcined to be transformed into a continuous metal oxide layer, thereby completing the modification of the porous substrate. The details of the embodiments of the disclosure will be described and discussed below.

First, a porous substrate, such as a porous metal substrate, is provided. The pore diameter of the porous substrate may be about 1-30 μm. In preferred embodiments, the porous metal substrate may comprise porous stainless steel such as stainless steel 301, 304, 321, 316, 304L, 316L, 410, 416, 420, and 430.

Then, a metal hydroxide layer is coated on the porous substrate. It is to be noted that the metal hydroxide layer is preferably made of a material that has a coefficient thermal expansion (CTE) and/or crystal lattice close to that of the porous substrate (the largest CTE difference may reach 1.2×10⁵ K⁻¹) to achieve enhanced structural stability, for example, enhanced adhesion and so on, so that there is good material compatibility between the metal oxide layer obtained after calcination (i.e. the modifying layer) and the porous substrate. The metal hydroxide layer may comprise magnesium hydroxide, aluminum hydroxide, chromium hydroxide, lithium hydroxide, sodium hydroxide, potassium hydroxide, zinc hydroxide, iron hydroxide, nickel hydroxide, manganese hydroxide, calcium hydroxide, copper hydroxide, or combinations thereof. The metal hydroxide layer may have a thickness of about 0.1-5 μm. However, the thickness may be adjusted based on need and on the principle of not overly blocking the pores of the porous substrate. The coating of the metal hydroxide layer may be by a method such as an electrochemical electroplating, hot dip plating, physical vapor deposition, chemical vapor deposition, co-precipitation, hydrothermal method, or other suitable methods. In some embodiments, co-precipitation may be used, for example, the co-precipitation method proposed by Sissoko et al. (I. Sissoko, E. T. Iyagba, R. Sahai, P. Biloen, J. Solid State Chem., 1985, 60, 283-288), which is herein incorporated in its entirety by reference. In the co-precipitation method, a mixture of a plurality of metal salts, for example a mixture of sodium salt, aluminum salt, and carbonate salt, is dissolved in a high concentration basic solution. The high concentration basic solution with metal salts added is then heated at a temperature of about 60-90° C. and continuously stirred for about 12-18 hours to form the metal hydroxide layer. In preferred embodiments, the method for fabricating “layered double hydroxide (LDH)” proposed by Hsieh et al. may be used, which is herein incorporated in its entirety by reference, to form the metal hydroxide layer of the present disclosure. Basically, the substrate is immersed in a basic solution containing two different metal cations (M_{A}^{z+} and M_{B}³⁺, z=1 or 2) to form highly oriented layered double oxide (i.e. the metal hydroxide layer), wherein M_{B} is the major metal element and M_{A} is the secondary metal element of the metal hydroxide layer. Furthermore, the thickness of the metal hydroxide layer may be controlled by controlling the growth time and the number of times of immersion. For example, the longer the immersion time and the higher the number of times of immersion, the larger the thickness of the metal hydroxide layer. The layered double hydroxide can be described with the following formula:

[M_{A}_{_{1-X}}_{^{z+}}M_{B}_{_{X}}_{³⁺}(OH)₂]^{A+}[X^{m-}]A/m·mH₂O

In some embodiments, X may be about 0.2-0.33. M_{B}³⁺ may comprise for example Al³⁺, Mn³⁺, Ni³⁺, Fe³⁺, or Cr³⁺. M_{A}^{z+} may comprise for example Ni²⁺, Mg²⁺, Zn²⁺, Ca²⁺, Cu²⁺, Mn²⁺, Li⁺, Na⁺, or K⁺. X^{m-} may comprise for example CO₃²⁻, NO₃⁻, Cl⁻, SO₄⁻, OH⁻, PO₄⁻, or I⁻.

Then, the porous substrate with the metal hydroxide layer is calcined to transform the metal hydroxide layer into a continuous metal oxide layer, thereby forming a modified porous substrate. In an embodiment, the metal hydroxide layer is the layered double hydroxide described above and comprises the two different metals M_{A} and M_{B} described above. Based on the total weight of the metal hydroxide layer, in some embodiments, the weight content (wt %) of M_{B} is significantly higher than that of M_{A}, and M_{A} only exists in trace amounts, for example, M_{A} is present in an amount of only about 2.5-3.2 wt %. In alternative embodiments, M_{A} may be present in an amount of about 2.5-35 wt %. In some embodiments, M_{B} may be present in an amount of about 20-25 wt %, based on the total weight of the metal hydroxide layer, and M_{A} may be present in an amount of 0.5-30 wt %, based on the total weight of the metal hydroxide layer. In some embodiments, the calcination temperature may be about 300-1200° C., or 300-600° C., and the calcination time may be at least about 10 minutes, for example 10-60 minutes. Since the calcination temperature may have an effect on the phase formation in metal hydroxides, the calcination temperature may be adjusted to obtain particular phases. For example, in some embodiments where the metal oxide layer is an Al₂O₃ layer, if the calcination is between 450-800° C., γ-Al₂O₃ may be obtained. In some embodiments, the metal oxide layer may have a thickness of about 0.1-3 μm. The thickness of the metal oxide layer is preferably controlled so that the modified porous substrate has a pore diameter of about 1-3 μm. Furthermore, compared with forming a layer of metal oxide particles on the porous substrate, forming a continuous metal oxide layer on the porous substrate may have anchoring effects. Thus, there is enhanced adhesion between the continuous metal oxide layer and the porous substrate, and the thickness of the metal oxide layer is more uniform.

After the metal hydroxide layer is calcined to be transformed into the metal oxide layer, a gas-selective film layer may be optionally formed to form a gas separation module. The gas-selective film layer may be formed by any suitable method such as an electroless plating, electroplating, sputtering, chemical vapor deposition, or plating method and so on. In addition, a suitable material for the film layer may be chosen to separate specific gases. It is to be noted that, similarly, the material for the film layer may have a CTE and/or lattice similar to that of the metal oxide layer so that there is enhanced structural stability between the film layer and the metal oxide layer, such as enhanced adhesion and so on. In some embodiments, the gas-selective film layer may be an inorganic film layer comprising for example Pd, Pd—Ag alloys, Pd—Cu alloys, vanadium alloys, niobium alloys, or tantalum alloys. In some embodiments, a Pd film may be used as the gas-selective film layer. The Pd film may be formed and the gas separation module using the Pd film may be operated according to the journal article by Chi et al. (Y. Chi, P. Yen, M. Jeng, S. Ko, and T. Lee, Int. J. Hydrogen Energy, 2010, 35, 6303-6310), which is herein incorporated in its entirety by reference. In this journal article, the metal hydroxide layer is activated by solutions each containing 5 nCl₂, de-ionized water, PdCl₂, and HCl, respectively, and subsequent to the activation electroless plating is carried out to form a Pd layer on the metal hydroxide layer. In some embodiments, the thickness of the gas-selective film layer may be about 3-10 μm.

In the present disclosure, the method for modifying a porous substrate has at least the following advantages: (1) enhanced adhesion between the metal oxide layer and the porous substrate; (2) the metal oxide layer has a uniform thickness; and (3) the metal oxide layer may act as an inter-layer for bonding between the porous substrate and the gas-selective film layer for more versatile applications, such as a gas separation module.

Some examples will be described below to describe the present disclosure more clearly and in more details. However, these examples do not intend to limit the scope of the present disclosure.

### Example 1

A 316 stainless steel substrate (316PSS hereafter) was immersed in a basic solution containing Li⁺ and Al³⁺ for an hour and was dried subsequent to being immersed. The basic solution was prepared by dissolving 0.3 g of AlLi alloy in 100 mL of pure water, and the concentration of Li⁺ was about 400 ppm, and the concentration of Al³⁺ was about 800 ppm. The above step of immersing and drying was repeated once to obtain a continuous aluminum hydroxide layer of sufficient thickness containing Li element and having the LDH structure (hereafter Li—Al LDH) coated on the surface of 316PSS, forming the Li—Al LDH/316PSS. The thickness of Li—Al LDH layer was about 3 μm.

Then, the Li—Al LDH/316PSS was calcined for 2 hours at 450° C. for transforming the Li—Al LDH layer into an Al₂O₃ layer, which is referred to as Al₂O₃/316PSS hereafter. In the present example, the Al₂O₃ layer had a γ phase for the most part.

Then, a Pd film was formed on the Al₂O₃ layer, wherein the Al₂O₃/316PSS was immersed successively in SnCl₂, de-ionized water, PdCl₂, 0.01 M HCl, and de-ionized water to activate Al₂O₃/316PSS. The activated Al₂O₃/316PSS was then placed in a Pd solution for electroless plating, forming a 316PSS sample with an Al₂O₃ layer and a Pd film layer formed thereon in the order described, and this sample will be referred to as Pd/Al₂O₃/316PSS hereafter. The thickness of the Pd film of Pd/Al₂O₃/316PSS was about 11.5 μm.

Table 1 lists the experimental results of helium permeation flux and hydrogen permeance measurement. Compared with the helium permeation flux of 316PSS, the helium permeation flux of Al₂O₃/316PSS was reduced to about half. After plating Pd on Al₂O₃/316PSS, Al₂O₃/316PSS, a hydrogen permeance measurement was carried out at 400° C. for three times in total, and the hydrogen permeance was found to be about 52-54 Nm³/m²-hr-atm^{0.5}, and the H₂/He selectivity was found to be about 261-321.

TABLE 1

| | Helium permeation flux |
|---|---|
| Sample | (m³/m²-hr) |
| 316PSS | 174.67 |
| Li—Al LDH/316PSS | 0.2766 |
| Al₂O₃/316PSS | 78.86 |
| Pd/Al₂O₃/316PSS | 0.0089 |
| Pd/Al₂O₃/316PSS | 52-54 Nm³/m²-hr-atm^{0.5} |
| (Hydrogen permeance) | |
| Pd/Al₂O₃/316PSS | 261-321 |
| (H₂/He selectivity) | |

The adhesion Pd layer to Al₂O₃/316PSS was tested using the Crosshatch Test, ASTM D3359, wherein a matrix was first formed on the Pd film by cutting into the film, then a special tape was applied to the Pd film with the matrix for 3 minutes, and lastly the special tape was pulled off in a direction obtained by rotating the direction in which the special tape was applied 180 degrees. The results showed that Pd film peel-off was only found at sites that had been cut into by the knife, and the Pd film still adhered to the Al₂O₃ modifying layer in its integrity in areas other than these sites. Thus, there was enhanced adhesion between the Al₂O₃ layer and the Pd layer fabricated according to the present disclosure, allowing for enhanced bonding between 316PSS and the Pd film.

### Example 2

With vigorous stirring, an amount of 250 mL of 0.4 M AlCl₃.6H₂O was added dropwise to a solution containing 600 mL of 1.5 M LiOH.6H₂O [symbol] (0.16/z)M Na_{z}A (A=CO₃²⁻, SO₄²⁻, and Fe(CN)₆⁴⁻), and upon the addition of Al₂(CO₃)₃.6H₂O into the solution, gel-type precipitates formed immediately. The initial pH value of the solution was 13, and the pH value changed as more Al₂(CO₃)₃.6H₂O was added to the solution to a final pH value of 10.2. After mixing, the mixture of Al₂(CO₃)₃.6H₂O and the solution formed a two-layer solution with its upper layer being supernatant and the bottom layer being gel-type precipitates, and the mixture of Al₂(CO₃)₃.6H₂O and the solution was gently stirred overnight. The gel-type precipitates were separated from the mixture by using filtration or centrifugal separation. Prior to the separation of the gel-type precipitates, the mixture underwent a hydrothermal process carried out at 160° C. for 59 hours. Subsequently, an excess amount of de-ionized water was used to wash the gel-type precipitates, and the washed gel-type precipitates were dried at 70° C. for about 15 hours.

Thus, the modifying layer fabricated by the method for modifying the porous substrate of the present disclosure provided enhanced adhesion to the porous substrate. Furthermore, a gas-selective film layer may be formed on the modifying layer, and the combination of the porous substrate, the modifying layer, and the film layer, may be used as a gas separation module to be applied in the separation of specific gases. Furthermore, the adhesion of the Pd layer to the modifying layer was enhanced. Therefore, enhanced bonding between the porous substrate and the gas-selective film layer may be achieved by using the modifying layer of the present disclosure.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for modifying a porous substrate, comprising:
coating a metal hydroxide layer on a porous substrate; and
calcining the porous substrate having the metal hydroxide layer to transform the metal hydroxide layer into a continuous metal oxide layer, forming a modified porous substrate.

2. The method for modifying a porous substrate as claimed in claim 1, wherein the porous substrate comprises porous stainless steel.

3. The method for modifying a porous substrate as claimed in claim 2, wherein a pore diameter of the porous stainless steel is about 1-30 μm.

4. The method for modifying a porous substrate as claimed in claim 1, wherein the metal hydroxide layer comprises magnesium hydroxide, aluminum hydroxide, chromium hydroxide, lithium hydroxide, sodium hydroxide, potassium hydroxide, zinc hydroxide, iron hydroxide, nickel hydroxide, manganese hydroxide, calcium hydroxide, copper hydroxide, or combinations thereof.

5. The method for modifying a porous substrate as claimed in claim 1, wherein a method for coating the metal hydroxide layer comprises an electrochemical electroplating, hot dip plating, physical vapor deposition, chemical vapor deposition, co-precipitation, or hydrothermal method.

6. The method for modifying a porous substrate as claimed in claim 1, wherein the metal hydroxide layer is a layered double hydroxide, and a process for coating the metal hydroxide layer comprises a step of placing the porous substrate in a basic solution, wherein the basic solution comprises ions of a first metal corresponding to a metal of the metal hydroxide layer and ions of a second metal different from the first metal.

7. The method for modifying a porous substrate as claimed in claim 6, wherein the ions of the first metal comprise Al³⁺, Mn³⁺, Ni³⁺, Fe³⁺, or Cr³⁺, and the ions of the second metal comprise Ni²⁺, Mg²⁺, Zn²⁺, Ca²⁺, Cu²⁺, Mn²⁺, Li⁺, Na⁺, or K⁺.

8. The method for modifying a porous substrate as claimed in claim 6, wherein the second metal is present in an amount of about 2.5-35 wt %, based on a total weight of the metal hydroxide layer.

9. The method for modifying a porous substrate as claimed in claim 6, wherein the metal oxide layer comprises the first metal and the second metal.

10. The method for modifying a porous substrate as claimed in claim 1, wherein the calcination temperature is about 300-600° C.

11. The method for modifying a porous substrate as claimed in claim 1, wherein the metal oxide layer has a thickness of about 0.1-3 μm.

12. The method for modifying a porous substrate as claimed in claim 1, wherein a pore diameter of the modified porous substrate is about 1-3 μm.

13. The method for modifying a porous substrate as claimed in claim 1, further comprising forming a gas-selective film layer on the metal oxide layer, thereby forming a gas separation module.

14. The method for modifying the porous substrate as claimed in claim 13, wherein the gas-selective film layer comprises Pd, Pd—Ag alloys, Pd—Cu alloys, vanadium alloys, niobium alloys, or tantalum alloys.

15. A modified porous substrate, comprising:
a porous substrate; and
a continuous metal oxide layer, coated on the porous substrate, wherein the continuous metal oxide layer comprises a second metal that is different from a first metal corresponding to a metal of the metal oxide layer.

16. The modified porous substrate as claimed in claim 15, wherein the porous substrate comprises porous stainless steel.

17. The modified porous substrate as claimed in claim 16, wherein the porous stainless steel has a pore diameter of about 1-30 μm.

18. The modified porous substrate as claimed in claim 15, wherein the metal oxide layer comprises magnesium oxide, aluminum oxide, chromium oxide, lithium oxide, sodium oxide, potassium oxide, zinc oxide, iron oxide, nickel oxide, manganese oxide, calcium oxide, copper oxide, or combinations thereof.

19. The modified porous substrate as claimed in claim 15, wherein the metal oxide layer has a thickness of about 0.1-3 μm.

20. The modified porous substrate as claimed in claim 15, wherein a pore diameter of the modified porous substrate is about 1-3 μm.

21. The modified porous substrate as claimed in claim 15, wherein the ions of the second metal comprise Ni²⁺, Mg²⁺, Zn²⁺, Ca²⁺, Cu²⁺, Mn²⁺, Li⁺, Na⁺, or K⁺.

22. The modified porous substrate as claimed in claim 21, wherein the second metal is present in an amount of about 2.5-35 wt %, based on a total weight of the metal hydroxide layer.

23. The modified porous substrate as claimed in claim 15, further comprising forming a gas-selective film layer on the metal oxide layer, thereby forming a gas separation module.

24. The modified porous substrate as claimed in claim 23, wherein the gas-selective film layer comprises Pd, Pd—Ag alloys, Pd—Cu alloys, vanadium alloys, niobium alloys, or tantalum alloys.
